(19) United States
(12) Patent Application Publication
(10) Pub. No.: US 2007/0249127 A1
(43) Pub. Date: Oct. 25, 2007

(54) Electronic device including a semiconductor layer and a sidewall spacer and a process of forming the same

(75) Inventors: Rode R. Mora, Austin, TX (US); Vance H. Adams, Austin, TX (US); Venkat R. Kolagunta, Austin, TX (US); Michael D. Turner, San Antonio, TX (US); Toni D. Van Gompel, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: Freescale Semiconductor, Inc., Austin, TX (US)

(21) Appl. No.: 11/409,882

(22) Filed: Apr. 24, 2006

(51) Int. Cl. H01L 21/336; H01L 27/12

(52) U.S. Cl. 438/295; 257/347

(57) ABSTRACT

An electronic device can include a substrate, an insulating layer, and a semiconductor layer overlying the insulating layer, wherein the insulating layer lies between the substrate and the semiconductor layer. In one aspect, a process of forming the electronic device can include patterning the semiconductor layer to define an opening extending to the insulating layer. The semiconductor layer has a sidewall and a surface, the surface is spaced apart from the insulating layer, and the sidewall extends from the surface towards the insulating layer. The process can also include forming a sidewall spacer adjacent to the sidewall, wherein the sidewall spacer lies within the opening and adjacent to the sidewall, and is spaced apart from the surface. In another aspect, the electronic device can include a field isolation region including the sidewall spacer.

### RELATED APPLICATIONS

The present disclosure is related to U.S. patent application Ser. No. ______, entitled “Process of Forming an Electronic Device Including a Layer Formed Using an Inductively Coupled Plasma” by Turner et. al. filed on ______, 2006 (Attorney Docket Number SC14825TP), and U.S. patent application Ser. No. ______, entitled “Electronic Device Including a Semiconductor Layer and Another Layer Adjacent to an Opening Within the Semiconductor Layer and a Process of Forming the Same” by Van Gompel et. al. filed on ______, 2006 (Attorney Docket Number SC14846TP), all of which are assigned to the current assignee hereof and incorporated by references in their entireties.

### BACKGROUND

1. Field of the Disclosure

The present disclosure relates to electronic devices and processes, and more particularly to electronic devices including semiconductor layers and sidewall spacers and processes of forming the same.

2. Description of the Related Art

As device performance becomes more and more demanding, semiconductor devices are now formed using semiconductor-on-insulator (“SOI”) substrates. In order to achieve a reasonably high component density, trench field isolation regions are typically formed between semiconductor devices. Typically, a trench liner is formed to help round the top corners of a semiconductor layer to improve gate dielectric integrity.

FIG. 1 includes an illustration of a cross-sectional view of a portion of an electronic device. The electronic device includes a substrate 12, an insulating layer 14, which can be a buried oxide, and a semiconductor layer 162 that overlies the insulating layer 14. The semiconductor layer 162 is patterned to form openings that extend through the semiconductor layer 162 to the insulating layer 14. A thermal oxidation is typically performed and grows a liner layer 164. During the formation of the liner layer 164, top corners 166 of the semiconductor layer 162 are rounded in order to improve gate dielectric integrity. However, the thermal oxidation also causes corner rounding near the bottom of the semiconductor layer 162, as seen with rounded bottom corners 168. The rounded bottom corners 168 within the semiconductor layer 162 near the insulating layer 14 are undesired. An insulating layer 18 can then be formed within the openings, with portions of the insulating layer 18 overlying the semiconductor layer 162 being removed using a conventional process. During subsequent thermal cycles, unacceptable levels of stress may be exerted by the trench field isolation regions (combination of the liner layer 164 and insulating layer 18) onto the semiconductor layer 162. The stress may cause electrical characteristics of the devices to change, defects, faults, fractures to form within the semiconductor layer 162, or, in extreme cases, delamination of the semiconductor layer 162 from the insulating layer 14.

Another attempt to address the bird's beak has been to form the opening extending through the semiconductor layer 162 and form a nitride layer along the bottom of the opening and not form any of the nitride layer along the sidewalls of the semiconductor layer 162 near the upper corners 166. In theory, the upper corners 166 of the semiconductor layer 162 should be exposed during a subsequent thermal oxidation, while the lower corners 168 are protected. The nitride layer can be deposited by evaporating the nitride layer, sputtering the nitride layer, or using a thermal chemical vapor technique. In practice, this technique does not work.

Sputtering is characterized by a long mean free path and no significant surface migration. Along the sidewalls, the nitride layer will be thicker at the upper corners 166 and thinner at the lower corners 168, when measured in a direction perpendicular to the sidewalls of the semiconductor layer 162. A collimator can reduce the sidewall deposition, but the deposition would still be thicker at the upper corners 166 as compared to the lower corners 168. Thus, thermal oxidation would round the upper corners 166 and the lower corners 168. Evaporation is more conformal and less directional as compared to sputtering. Therefore, a significant amount of the nitride layer will deposit along the sidewall.

A thermal chemical vapor deposition is a deposition performed without using a plasma. When forming a nitride layer using low pressure chemical vapor deposition (“LPCVD”), dichlorosilane and ammonia are typically reacted at a temperature in a range of approximately 700° C. to approximately 800° C. under vacuum and without a plasma. The deposition is characterized by a rapid surface migration and forms a substantially conformal nitride layer, which would deposit about the same thickness of nitride along the bottom of the opening as it would along the sidewalls of the semiconductor layer 162. A conformal deposition would deposit nearly equivalent thicknesses of the nitride layer along the sidewall of the semiconductor layer 162.

Therefore, a layer having a significant thickness along a bottom of an opening with no or very little sidewall coverage while protecting the lower corners 168 and allowing rounding of the upper corners 166 of the semiconductor layer 162 has not been enabled. Sputtering and evaporating a nitride layer would deposit a layer along the sidewall that would be locally thicker near the upper corners 166 as compared to the lower corners 168, and a thermal CVD process can produce a conformal layer.

### BRIEF DESCRIPTION OF THE DRAWINGS

Embodiments are illustrated by way of example and are not limited in the accompanying figures.

FIG. 1 includes an illustration of a cross-sectional view of a portion of an electronic device that includes an SOI substrate, wherein the semiconductor layer has rounded corners. (Prior Art)

FIG. 2 includes an illustration of a cross-sectional view of a portion of an electronic device workpiece after forming a mask.

FIG. 3 includes an illustration of a cross-sectional view of the workpiece of FIG. 2 after forming an opening extending through a semiconductor layer.

FIG. 4 includes an illustration of a cross-sectional view of the workpiece of FIG. 3 after forming a triangular sidewall spacer in accordance with an embodiment.

FIG. 5 includes an illustration of a cross-sectional view of the workpiece of FIG. 3 after forming a parabolic sidewall spacer in accordance with another embodiment.

FIG. 6 includes an illustration of a cross-sectional view of the workpiece of FIG. 3 after forming a rectangular sidewall spacer in accordance with still another embodiment.

FIG. 7 includes an illustration of a cross-sectional view of the workpiece of FIG. 4 after rounding corners of the semiconductor layer near the top of the semiconductor layer.

FIG. 8 includes an illustration of a cross-sectional view of the workpiece of FIG. 7 after forming an insulating layer that fills the opening.

FIG. 9 includes an illustration of a cross-sectional view of the workpiece of FIG. 8 after forming a field isolation region is substantially completed.

FIG. 10 includes an illustration of a cross-sectional view of the workpiece of FIG. 9 after removing remaining portions of layers overlying the semiconductor layer.

FIG. 11 includes an illustration of a cross-sectional view of the workpiece of FIG. 10 after forming electronic components.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

An electronic device can include a substrate, an insulating layer, and a semiconductor layer, wherein the insulating layer lies between the substrate and the semiconductor layer. An opening in the semiconductor layer may extend to the insulating layer. The electronic device can include a sidewall spacer lying within the opening. In one aspect, a process of forming an electronic device can include patterning the semiconductor layer to define the opening. After patterning a semiconductor layer, the semiconductor layer can have a sidewall and a surface, the surface can be spaced apart from the insulating layer, and the sidewall can extend from the surface towards the insulating layer. The process can also include forming a sidewall spacer adjacent to the sidewall, wherein the sidewall spacer lies within the opening and adjacent to the sidewall, and is spaced apart from the surface.

In another aspect, an electronic device can include the semiconductor layer. The semiconductor layer can have a sidewall and a surface, the surface is spaced apart from the insulating layer; and the sidewall extends from the surface towards the insulating layer. The electronic device can also include a field isolation region overlying the insulating layer and lying adjacent to the sidewall of the semiconductor layer. The field isolation region includes a sidewall spacer adjacent to the sidewall, and the sidewall spacer lies adjacent to the sidewall and is spaced apart from the surface.

Before addressing details of embodiments described below, some terms are defined or clarified. The term “elevation” is intended to mean the closest distance from a layer, a feature, or a surface of a layer or feature to a reference plane, such as a primary surface of a substrate.

The term “high-k” is intended to mean a dielectric constant of at least 8.0.

The term “primary surface” is intended to mean a surface of a substrate or a layer overlying the substrate or a portion of the substrate or layer from which a transistor is subsequently formed. The primary surface may be an original surface of a base material before forming any electronic components or may be a surface of the semiconductor layer that overlies the base material. For example, an exposed surface of a semiconductor layer of a semiconductor-on-insulator substrate can be a primary surface, and not the original surface of the base material.

The term “substrate” is intended to mean a base material. An example of a substrate includes a quartz plate, a monocrystalline semiconductor wafer, a semiconductor-on-insulator wafer, etc. The reference point for a substrate is the beginning point of a process sequence.

The term “workpiece” is intended to mean a substrate and, if any, one or more layers one or more structures, or any combination thereof attached to the substrate, at any particular point of a process sequence. Note that the substrate may not significantly change during a process sequence, whereas the workpiece significantly changes during the process sequence. For example, at the beginning of a process sequence, the substrate and workpiece are the same. After a layer is formed over the substrate, the substrate has not changed, but now the workpiece includes the combination of the substrate and the layer.

Group numbers corresponding to columns within the Periodic Table of the elements use the “New Notation” convention as seen in the CRC Handbook of Chemistry and Physics, 81^{st} Edition (2000).

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B is true (or present).

Additionally, for clarity purposes and to give a general sense of the scope of the embodiments described herein, the use of the “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Unless otherwise defined, all technical and scientific terms used herein have the same meaning as commonly understood by one of ordinary skill in the art to which this invention belongs. All publications, patent applications, patent, and other references mentioned herein are incorporated by reference in their entirety. In case of conflict, the present specification, including definitions, will control. In addition, the materials, methods, and examples are illustrative only and not intended to be limiting.

Other features and advantages of the invention will be apparent from the following detailed description, and from the claims.

To the extent not described herein, many details regarding specific materials, processing acts, and circuits are conventional and may be found in textbooks and other sources within the semiconductor and microelectronic arts.

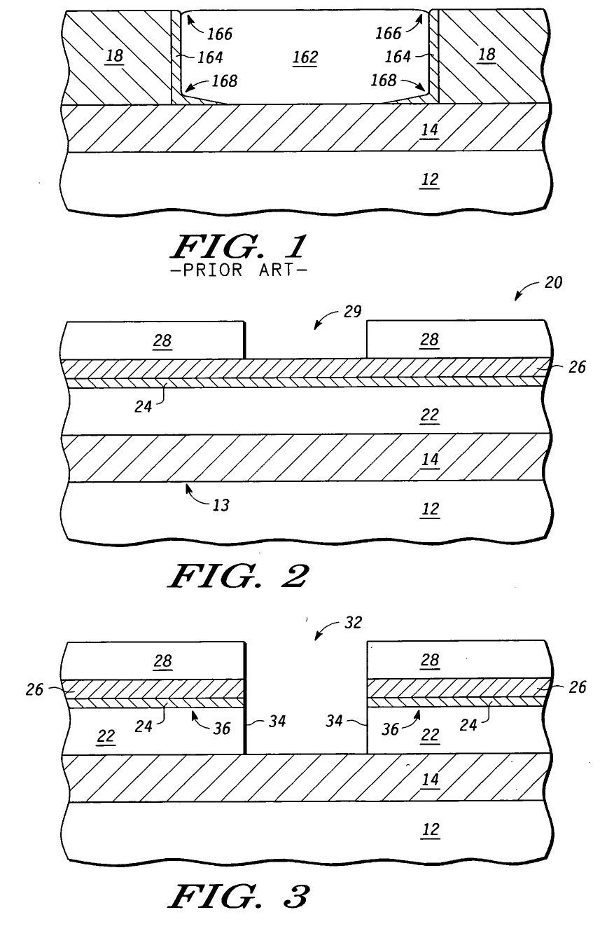

FIG. 2 includes an illustration of a cross-sectional view of a portion of an electronic device workpiece 20, which includes a substrate 12, an insulating layer 14, and a semiconductor layer 22. The substrate 12 can include an electronic device substrate, such as a flat panel substrate, a semiconductor device substrate, or another conventional substrate used for forming electronic devices. The insulating layer 14 overlies the substrate 12 at a primary surface 13.

The insulating layer 14 includes an oxide, nitride, or a combination thereof. The insulating layer 14 (usually referred to as a buried oxide layer or a BOX layer) has a thickness sufficient to substantially reduce parasitic capacitance between the substrate 12 and subsequently formed electronic devices within the semiconductor layer 22. In one embodiment, the insulating layer 14 has a thickness of at least 100 nm.

The semiconductor layer 22 can include a Group 14 element (e.g., C, Si, Ge, etc.), a III-V semiconductor, a II-VI semiconductor, or any combination thereof. In one embodiment, the semiconductor layer 22 is a substantially monocrystalline silicon or silicon germanium layer. The thickness of the semiconductor layer 22 is in a range of approximately 10 to approximately 200 nm. The combination of the substrate 12, insulating layer 14, and semiconductor layer 22 may be obtained from a commercially available source or the insulating layer 14 and semiconductor layer 22 can be formed from or over the substrate 12 using a conventional or proprietary processing sequence.

A pad layer 24 and an oxidation-resistant layer 26 are formed over the semiconductor layer 22, as illustrated in FIG. 2. In one embodiment, the pad layer 24 includes an oxide (e.g., silicon dioxide, silicon oxynitride, etc.) that is thermally grown from or deposited over the semiconductor layer 22, and the oxidation-resistant layer 26 includes a nitride (e.g., silicon nitride, silicon-rich silicon nitride, etc.) that is deposited over the pad layer 24. In one non-limiting embodiment, the pad layer 24 can have a thickness in a range of approximately 2 to approximately 40 nm, and the oxidation-resistant layer 26 can have a thickness in a range of approximately 10 to approximately 200 nm.

A mask 28 is formed over the pad layer 24 and the oxidation-resistant layer 26 using a conventional or proprietary lithographic technique to define an opening 29. In one embodiment, the mask 28 includes a resist material, such as photoresist or deep ultraviolet resist.

As illustrated in FIG. 3, the oxidation-resistant layer 26, the pad layer 24, and the semiconductor layer 22 are patterned to form an opening 32 that extends through those layers to expose the insulating layer 14 along a bottom of the opening 32. The semiconductor layer 22 includes surfaces 36 that are spaced apart from the insulating layer 14. After forming the opening 32, the semiconductor layer 22 includes sidewalls 34 lying along the opening 32 and extending from the surfaces 36 towards the insulating layer 14. In one embodiment, the openings in the oxidation-resistant layer 26 and the pad layer 24 and the sidewalls 34 of the opening 32 are substantially coterminous with one another. The sidewalls 34 can be substantially vertical or may include a slight taper (i.e., slightly off vertical).

In one embodiment, the oxidation-resistant layer 26 includes silicon nitride, the pad layer 24 includes silicon dioxide, and the semiconductor layer 22 includes silicon or silicon germanium. The opening 32 can be formed by dry etching the layers. Different etch chemistries can be used during the etch. The oxidation-resistant layer 26 can be etched using an etch chemistry that is tailored for silicon nitride and has good selectivity to oxide. The pad layer 24 can be etched using an etch chemistry that is tailored for silicon dioxide and has good selectivity to silicon or silicon germanium. The semiconductor layer 22 can be etched using an etch chemistry that tailored to silicon or silicon germanium. The same etch chemistries can be used for combinations of some of the layers. For example, the same etch chemistry may be used for the oxidation-resistant layer 26 and pad layer 24. Such etch chemistry may have good selectivity to silicon or silicon germanium. Alternatively, the same etch chemistry may be used for the pad layer 24 and the semiconductor layer 22. Still other etch chemistries can be used, particularly if the composition of the oxidation-resistant layer 26, the pad layer 24, the semiconductor layer 22, or any combination thereof would be different from those previously described. After reading this specification, skilled artisans will be able to select etch chemistries that meet their needs or desires.

Each of etching of the oxidation-resistant layer 26, the pad layer 24, and the semiconductor layer 22 may be performed as a timed etch or using endpoint detection with an optional timed overetch.

After the opening 32 has been formed, the mask 28 can be removed using a conventional or proprietary ashing technique. In an alternative embodiment, the mask 28 can be removed after patterning the oxidation-resistant layer 26, after patterning the pad layer 24, or after forming the opening 32. In this embodiment, the oxidation-resistant layer 26 or combination of the oxidation-resistant layer 26 and the pad layer 24 can act as a hard mask while etching the opening 32 into the semiconductor layer 22.

In one set of embodiment, sidewall spacers may be formed. As used herein, the shapes of the sidewall spacers refer to two-dimensional shapes of the spacers, as seen from a cross sectional view of the sidewall spacer. “Parabolic” is used to describe a shape that can be half of a parabola.

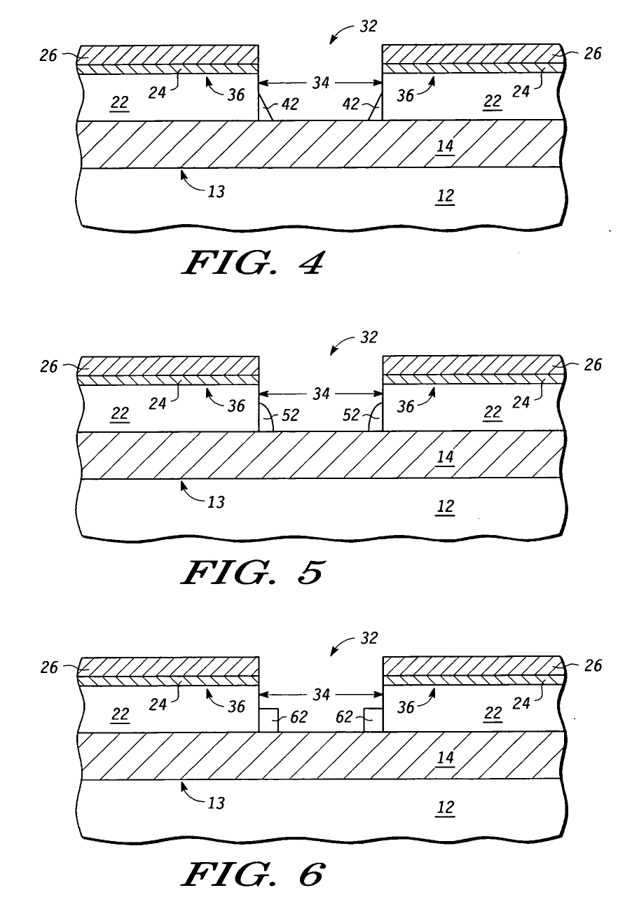

In FIG. 4, triangular sidewall spacers 42 can be formed over the insulating layer 14 and along the sidewalls 34 of the semiconductor layer 22, in FIG. 5, parabolic sidewall spacers 52 can be formed over the insulating layer 14 and along the sidewalls 34 of the semiconductor layer 22, and in FIG. 6, rectangular sidewall spacers 62 can be formed over the insulating layer 14 and along the sidewalls 34 of the semiconductor layer 22. The triangular sidewall spacers 42, the parabolic sidewall spacers 52, the rectangular sidewall spacers 62, or any combination thereof can be formed by a conventional or proprietary deposition of a layer and anisotropically etching the layer using a conventional or proprietary processing sequence. Highest points (e.g., farthest from the primary surface of the substrate 12) of the triangular sidewall spacers 42, the parabolic sidewall spacers 52, the rectangular sidewall spacers 62, or any combination thereof lies at an elevation significantly lower than the surface 36. Although not illustrated, a sidewall spacer having a different shape could also be used.

The sidewall spacers can help to slow or substantially prevent oxidation of the semiconductor layer 22 near the insulating layer 14 during a subsequent thermal oxidation operation. Thus, the material for the layer used to form the sidewall spacers can include a nitride, an oxide, an oxynitride, silicon, germanium, another suitable material used in semiconductor devices and capable of withstanding a processing temperature of at least 1000° C., or any combination thereof. In one embodiment, a nitride layer can be used, and in a particular embodiment, silicon nitride can be used.

The sidewall spacers can be formed by depositing a layer of material. In one non-limiting embodiment, the layer can be deposited by a plasma-enhanced chemical vapor deposition technique (“PECVD”) or a high-density plasma (“HDP”) technique. A difference between PECVD and HDP is that the latter has an inductively coupled plasma. In still another embodiment, a thermal nitride deposition (e.g., a conventional or proprietary low pressure chemical vapor deposition (“LPCVD”) can be used. As used in this specification, LPCVD does not include use of a plasma.

The PECVD technique can deposit in a range of approximately of 50% to approximately 100% conformal on the sidewall. As used in this specification, % conformal refers to a thickness of the layer measured at the sidewall in a direction substantially perpendicular to the sidewall divided by a thickness of the layer measured along an exposed flat surface of the workpiece, expressed as a percentage. The HDP technique can deposit in a range of approximately of 20% to approximately 50% conformal on the sidewall. Less material is deposited along the sidewall using the HDP technique because of a lower pressure is used. The thermal nitride deposition technique can deposit in a range of approximately of 80% to approximately 100% conformal on the sidewall.

Deposition parameters when forming a silicon nitride layer are described. For the PECVD technique, the pressure can be in a range of approximately 1 to approximately 10 Torr, and for the HDP technique, the pressure can be in a range of approximately 1 to approximately 10 mTorr.

For the PECVD technique, the power on a 200 mm (nominal) substrate can be in a range of approximately 25 to approximately 200 W (approximately 0.08 to approximately 0.64 W/cm²). For the HDP technique, the ionizing power on a 200 mm (nominal) substrate can be in a range of approximately 1000 to approximately 5000 W (approximately 3.2 to 16 W/cm²). In one embodiment, the HDP deposition can be performed without any biasing power (i.e., unbiased) to reduce the sidewall deposition. In another embodiment, a biasing power of approximately 1000 W to approximately 3000 W (approximately 3.1 to approximately 9.6 W/cm²) could be applied to shape the deposition to the desired profile. A higher biasing power can result in greater deposition on the sidewall. After reading this specification, skilled artisans will appreciate that power fluxes (power/unit area) will allow actual power used to be scaled with changing substrate size.

In a particular, non-limiting embodiment, the triangular sidewall spacers 42 and parabolic sidewall spacers 52 can be formed from a layer deposited using a PECVD technique or a HDP technique, and the rectangular sidewall spacers 62 can be formed from a layer deposited using an LPCVD technique.

To the extent particular deposition parameters are not described (e.g., gas flow rates, frequencies for power supplies, etc.), conventional or proprietary deposition parameters can be used. After reading this specification, skilled artisans will appreciate that different operating parameters could be used for the silicon nitride layer or if a different composition (e.g., silicon oxynitride, etc.) would be deposited.

In one embodiment, after depositing the layer of material, the layer can be etched to form the triangular sidewall spacers 42 in FIG. 4. In a non-limiting embodiment, the etch can be performed by using a relatively heavier polymerizing chemistry (as compared to etches to form the parabolic sidewall spacers 52 and rectangular sidewall spacers 62). In a particular embodiment, the etch chemistry can include CₐH_{b}F_{2a+2-b}, wherein a is 1 to 3, and b is 1 to 2a+1. In a more particular embodiment, the etch can be performed using CH₃F, CHF₃, CH₂F₂, or any combination thereof. To the extent particular etch parameters are not described (e.g., gas flow rates, frequencies for power supplies, etc.), conventional or proprietary deposition parameters can be used. After reading this specification, skilled artisans will appreciate that different operating parameters could be used for etching the silicon nitride layer or if a different composition (e.g., silicon oxynitride, etc.) would be etched.

In another embodiment, after depositing the layer of material, the layer can be etched to form the parabolic sidewall spacers 52 in FIG. 5. In a non-limiting embodiment, the etch can be performed by using a relatively lighter polymerizing chemistry, i.e., less polymerizing as compared to the etch used to form the triangular sidewall spacers 42. In a particular embodiment, the etch can be performed using CF₄ and HBr. In another embodiment, a different etch chemistry could be used. To the extent particular etch parameters are not described (e.g., gas flow rates, frequencies for power supplies, etc.), conventional or proprietary deposition parameters can be used. After reading this specification, skilled artisans will appreciate that different operating parameters could be used for etching the silicon nitride layer or if a different composition (e.g., silicon oxynitride, etc.) would be etched.

In still another embodiment, after depositing the layer of material, the layer can be etched to form the rectangular sidewall spacers 62 in FIG. 6. In a non-limiting embodiment, the etch can be performed by using a relatively lighter polymerizing chemistry, i.e., less polymerizing as compared to the etch used to form the triangular sidewall spacers 42. In a particular embodiment, the etch can be performed using SF₆ and HBr. In another embodiment, a different etch chemistry could be used. To the extent particular etch parameters are not described (e.g., gas flow rates, frequencies for power supplies, etc.), conventional or proprietary deposition parameters can be used. After reading this specification, skilled artisans will appreciate that different operating parameters could be used for etching the silicon nitride layer or if a different composition (e.g., silicon oxynitride, etc.) would be etched.

Other shapes (not illustrated) of sidewall spacers may be formed within the opening 32. These other shapes can be used as long as the corner of the semiconductor layer at the opening 32 and insulating layer 14 is substantially protected during a subsequent oxidation. The remainder of the formation process uses the triangular sidewall spacers 42 in FIG. 4 to simplify understanding of the remainder of the process flow. After reading this specification, skilled artisans will appreciate that other shapes of sidewall spacers, such as the parabolic sidewall spacers 52, the rectangular sidewall spacers 62, or any combination thereof could be used in forming the electronic components within the electronic device.

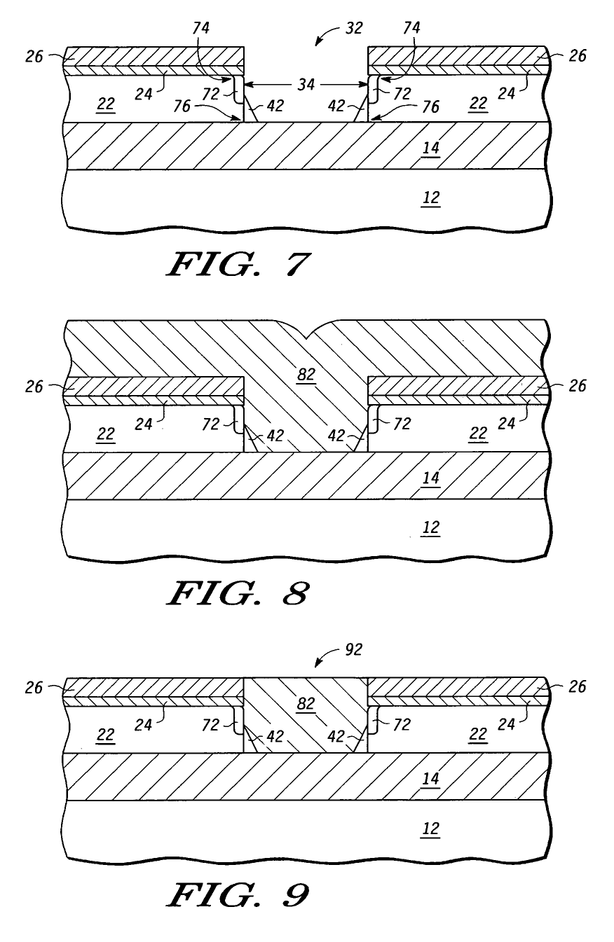

A liner layer 72 can be formed along the exposed surfaces of the semiconductor layer 22, as illustrated in FIG. 7. The liner layer 72 can include one or more insulating films. In one embodiment, the liner layer 72 is formed by thermally oxidizing a portion of the semiconductor layer 22 using an oxygen-containing ambient (e.g., O₂, O₃, N₂O, another suitable oxidizing species, or any combination thereof). The oxidation-resistant layer 26 does not significantly oxidize during the thermal oxidation, and therefore can act as an oxidation mask during thermal oxidation. In one embodiment, the liner layer 72 has a thickness in a range of approximately 1 to approximately 20 nm, and in a more particular embodiment, in a range of approximately 7 to approximately 11 nm.

The thermal oxidation can cause corner rounding of semiconductor layer 22, adjacent to the pad layer 24, which results in rounded corners 74. The rounded corners 74 lies at or near the top of the sidewalls 34 of the semiconductor layer 22. The rounded corners 74 helps to improve gate dielectric layer integrity. The triangular sidewall spacers 42 slow or substantially prevent oxidation of the semiconductor layer 22 at the corners 76 adjacent to the insulating layer 14. Thus, the triangular sidewall spacers 42 allows the liner layer 72 to be thicker than if liner layer 72 was formed when no sidewall spacers would be present adjacent to the bottom of the semiconductor layer 22.

In an alternative embodiment, the liner layer 72 can include one or more other insulating films that can be used in conjunction with or in place of the thermal oxide film. In one embodiment, a nitride film can be deposited using a conventional technique over the thermal oxide film. The nitride film can have a thickness in a range of approximately 1 to approximately 5 nm and may help to reduce erosion of the oxide film within the liner layer 72 during subsequent oxide etches, for example, when removing the pad layer 24, when forming and removing a sacrificial layer before forming a gate dielectric layer of the electronic device, etc.

In an alternative embodiment (not illustrated), the triangular sidewall spacers 42 can optionally be removed at this point in the process. For example, if the triangular sidewall spacers 42 include a metallic element, the removal may reduce the likelihood of adverse consequences (due to the presence of the metallic element throughout the remainder of the process sequence).

An insulating layer 82 is formed and substantially fills the rest of the opening 32, as illustrated in FIG. 8. The insulating layer 82 can include an oxide, a nitride, an oxynitride, or a combination thereof and can be deposited using a conventional or proprietary technique. In one specific embodiment, the insulating layer 82 is formed by depositing an oxide film from tetraethylorthosilicate (TEOS) to a thickness that is at least one half the depth of the opening 32, and typically is as thick as the depth of the opening 32. The insulating layer 82 may have an undulating upper surface, a substantially flat upper surface, or something in-between.

Portions of the insulating layer 82 lying outside the opening 32 and overlying the oxidation-resistant layer 26 are removed to form a field isolation region 92, as illustrated in FIG. 9. The field isolation region 92 includes the triangular sidewall spacers 42, the liner layer 72, and the insulating layer 82. In one embodiment, a conventional or proprietary chemical-mechanical polishing technique can be used, wherein the oxidation-resistant layer 26 can also act as a polish-stop layer. In another embodiment, the polishing operation could be continued until another layer underlying the oxidation-resistant layer 26 is reached.

In another embodiment, a conventional or proprietary etching process can be performed until the oxidation-resistant layer 26 is exposed, wherein the oxidation-resistant layer 26 can also act as an etch-stop layer. The etching may be performed as a timed etch or using endpoint detection (detecting the oxidation-resistant layer 26 has been reached) with a timed overetch. In one particular embodiment when the insulating layer 82 has an undulating surface, as deposited, a conventional or proprietary resist-etch-back process can be used. As the insulating layer 82 is etched, the etch chemistry may be changed before the oxidation-resistant layer 26 is reached to improve the etch selectivity (e.g., ratio of oxide etch rate to nitride etch rate is increased), and thus, decrease the likelihood of removing substantially all of the oxidation-resistant layer 26.

In FIG. 10, remaining portions of the oxidation-resistant layer 26 and the pad layer 24 are removed using a conventional or proprietary technique, if not previously removed when removing portions of the insulating layer 82 that were outside the trench. A wet etching technique, dry etching technique, or any combination thereof can be used to remove the oxidation-resistant layer 26, the pad layer 24, or both. In one embodiment, a dilute HF solution can be used to remove the pad layer 24. Relatively small amounts of the liner layer 72 and the insulating layer 82 may be removed if the pad layer 24, the liner layer 72, and the insulating layer 82 comprise substantially the same material (e.g., SiO₂). Such relatively small amounts typically do not significantly adversely affect the electronic device.

In another embodiment, not illustrated, a sacrificial oxide layer can be grown and removed at this point in the process. The sacrificial oxide layer can help to improve the surface quality of the semiconductor layer 22 before a gate dielectric layer or another layer is subsequently formed. The thickness of the sacrificial layer can be in a range of approximately 1 to approximately 20 nm. The sacrificial oxide layer may be formed in addition to or instead of the liner layer 72. If the liner layer 72 would not be formed, the sacrificial oxide layer can help to round the upper corners of the semiconductor layer 22 before a gate dielectric layer would be formed. The sacrificial oxide layer can be formed and removed using a conventional or proprietary process.

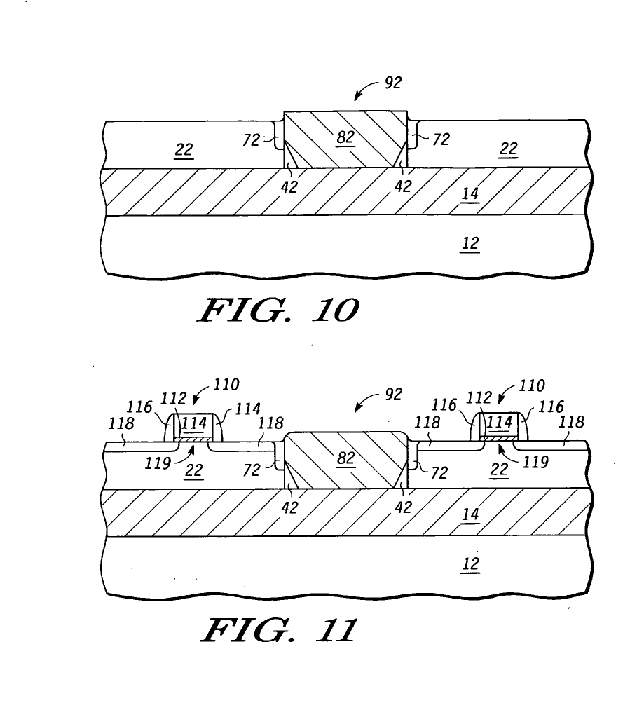

At this point in the process, electronic components, such as transistors 110, can be formed, as illustrated in FIG. 11. In one embodiment, the transistors 110 will have their active regions (i.e., source/drain and channel regions) formed within the semiconductor layer 22. The transistors 110 include an n-channel transistor, a p-channel transistor, or any combination thereof. Other electronic components, including a resistor, a capacitor, or any combination thereof, can be formed from portions of the semiconductor layer 22, if desired.

Optionally, a well dopant (not illustrated), a separate threshold adjust dopant, or other dopants may be introduced into portions of the semiconductor layer 22. An optional thermal cycle may be performed to activate the dopant(s). In another embodiment, the dopant(s) may be activated during subsequent processing.

A gate dielectric layer 112 is formed over the semiconductor layer 22, as illustrated in FIG. 11. The gate dielectric layer 112 can be formed using a conventional or proprietary growth technique, a deposition technique, or any combination thereof. The gate dielectric layer 112 can include one or more films of silicon dioxide, silicon nitride, silicon oxynitride, a metal-containing oxide, a metal-containing nitride, a metal-containing oxynitride, another high-k material, or any combination thereof. The gate dielectric layer 112 can have a thickness in a range of approximately 5 to approximately 50 nm in a substantially completed electronic device. In an alternative embodiment, the transistors 110 may have gate dielectric layers with different compositions, a different number of films within each gate dielectric layer, significantly different thicknesses, or any combination thereof.

Gate electrodes 114 are formed over the gate dielectric layer 112 using a conventional deposition and etch processing sequence. Each of the gate electrodes 114 can include one or more layers. The gate electrodes 114 can include a heavily doped amorphous silicon or polycrystalline silicon layer, a metal-containing layer, another suitable conductive layer, or any combination thereof. Each of the gate electrodes 114 has a thickness in a range of approximately 50 to approximately 300 nm. In an alternative embodiment, the transistors 110 may have gate electrodes with different compositions, a different number of films within each gate electrode, significantly different thicknesses, or any combination thereof.

The gate dielectric layer 112 and the gate electrodes 114 extend into and out of the drawing as illustrated in FIG. 11. Although not illustrated, the gate electrodes 114 may extend over the field isolation region 92 or a different field isolation region that is substantially similar to the field isolation region 92. Thus, each of the gate dielectric layer 112 and the gate electrodes 114 may lie adjacent to the surface 36 of the semiconductor layer 22 and adjacent to the rounded corner 74 of the semiconductor layer 22 (see FIG. 7).

An optional sidewall oxide layer (not illustrated) can be grown from exposed sides of the gate electrodes 114 to protect the gate electrodes 114 during subsequent processing. The thickness of the optional sidewall oxide layer can be in a range of approximately 2 to approximately 15 nm.

Sidewall spacers 116 and source/drain (“S/D”) regions 118 can be formed. In one embodiment, dopants for extension regions can be implanted after forming the gate electrodes 114 and before forming the sidewall spacers 116. The sidewall spacers 116 can be formed using conventional deposition techniques and may include an oxide layer, a nitride layer, or a combination thereof. Dopants for heavily doped regions can be implanted after forming the sidewall spacers 116. A thermal cycle can be performed to activate the dopants to form the S/D regions 118, which include extension and heavily doped regions. Portions of the semiconductor layer 22 lying under the gate electrodes 114 and between the S/D regions 118 are channel regions 119. At this point in the process, transistors 110 have been formed. Although not illustrated in FIG. 11, silicided regions can be formed from or over the gate electrodes 114, S/D regions 118, or any combination thereof. The silicided regions can be formed using a conventional or proprietary process.

Processing can be continued to form a substantially completed electronic device. One or more insulating layers, one or more conductive layers, and one or more passivating layers are formed using conventional techniques.

The formation of the triangular sidewall spacers 42, the parabolic sidewall spacers 52, the rectangular sidewall spacers 62, or any combination thereof before the rounded corners 74 are formed helps to reduce or substantially eliminate the bird's beak formation that would occur if the bottom corner of the semiconductor layer 22 would be exposed when forming the rounded corners 74. Also, the presence of the triangular sidewall spacers 42, the parabolic sidewall spacers 52, the rectangular sidewall spacers 62, or any combination thereof can help to redirect the stress on the semiconductor layer 22, such that compressive stress on the semiconductor layer 22 is reduced. Electrical performance of transistors, particularly n-channel transistors, can be improved as compared to transistors formed using the field isolation regions 18 in FIG. 1.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a process of forming an electronic device can include patterning a semiconductor layer to define an opening extending to an insulating layer, wherein the insulating layer lies between a substrate and the semiconductor layer. After patterning a semiconductor layer, the semiconductor layer can have a sidewall and a surface, wherein the surface is spaced apart from the insulating layer, and the sidewall extends from the surface towards the insulating layer. The process can also include forming a sidewall spacer adjacent to the sidewall, wherein the sidewall spacer lies within the opening and adjacent to the sidewall, and is spaced apart from the surface.

In one embodiment of the first aspect, forming the sidewall spacer can include forming the sidewall spacer such that a first elevation, corresponding to a highest point of the sidewall spacer, lies closer to a primary surface of the substrate as compared to a second elevation, corresponding to the surface of the semiconductor layer. In another embodiment, forming the sidewall spacer can include forming the sidewall spacer, wherein as seen from a cross-sectional view, the sidewall spacer has a triangular shape. In still another embodiment, forming the sidewall spacer includes forming the sidewall spacer, wherein as seen from a cross-sectional view, the sidewall spacer has a parabolic shape. In yet another embodiment, forming the sidewall spacer can include forming the sidewall spacer, wherein as seen from a cross-sectional view, the sidewall spacer has a rectangular shape.

In a further embodiment of the first aspect, the process can further include oxidizing the semiconductor layer. The semiconductor layer can include a first corner and a second corner, wherein the first corner is adjacent to the surface, and the second corner is adjacent to the insulating layer. The first corner can become rounded during oxidizing the semiconductor layer, and the second corner can substantially maintain its shape during oxidizing the semiconductor layer. In a particular embodiment, the process can further include depositing an oxide layer that substantially fills the opening, and polishing the oxide layer to remove a portion of the oxide layer lying outside the opening. In a more particular embodiment, the process can further include forming a patterned oxidation-resistant layer over the semiconductor layer before patterning the semiconductor layer, and removing the patterned oxidation-resistant layer after removing the material.

In still a further embodiment of the first aspect, forming the sidewall spacer can include depositing a nitride layer. In a particular embodiment, forming the first layer is performed using an inductively coupled plasma. In yet a further embodiment, the process can further include forming a gate dielectric layer adjacent to the semiconductor layer, and forming a gate electrode, wherein the gate dielectric layer lies between the semiconductor layer and the gate electrode.

In a second aspect, a process of forming an electronic device can include forming a patterned oxidation-resistant layer over a semiconductor layer, wherein the insulating layer lies between a substrate and the semiconductor layer. The process can also include patterning the semiconductor layer to define an opening extending to the insulating layer. After patterning a semiconductor layer, the semiconductor layer can have a sidewall and a surface, the surface can be spaced apart from the insulating layer, and the sidewall extends from the surface toward the insulating layer. The process can further include forming a sidewall spacer adjacent to the sidewall, wherein the sidewall spacer includes a nitride material, the sidewall spacer lies within the opening and adjacent to the sidewall, and is spaced apart from the surface. A first elevation, corresponding to a highest point of the sidewall spacer, may lie closer to a primary surface of the substrate as compared to a second elevation, corresponding to the surface of the semiconductor layer. The process can still further include oxidizing the semiconductor layer after forming the sidewall spacer. The semiconductor layer can include a first corner and a second corner, wherein the first corner is adjacent to the surface, and the second corner is adjacent to the insulating layer. The first corner can become rounded during oxidizing the semiconductor layer, and the second corner can substantially maintain its shape during oxidizing the semiconductor layer.

The process can also include depositing an oxide layer that substantially fills the opening, polishing the oxide layer to remove a portion of the oxide layer lying outside the opening, and removing the patterned oxidation-resistant layer after removing the material. The process can further include forming a gate dielectric layer adjacent to the semiconductor layer and forming a gate electrode. The gate dielectric layer can lie between the semiconductor layer and the gate electrode, and the gate dielectric layer and the gate electrode can be part of an n-channel transistor.

In a third aspect, an electronic device can include a substrate, an insulating layer, a semiconductor layer, wherein the insulating layer lies between the substrate and the semiconductor layer. The semiconductor layer can have a sidewall and a surface, the surface is spaced apart from the insulating layer, and the sidewall extends between the insulating layer and the surface. The electronic device can also include a field isolation region overlying the insulating layer and lying adjacent to the sidewall of the semiconductor layer, wherein the field isolation region includes a sidewall spacer that lies adjacent to the sidewall and is spaced apart from the surface.

In one embodiment of the third aspect, a first elevation, corresponding to a highest point of the sidewall spacer, may lie closer to a primary surface of the substrate as compared to a second elevation, corresponding to the surface of the semiconductor layer. In another embodiment, as seen from a cross-sectional view, the sidewall spacer can have a triangular shape, a parabolic shape, a rectangular shape, or any combination thereof. In still another embodiment, the semiconductor layer can include a first corner and a second corner, the first corner is adjacent to the surface, and the second corner is adjacent to the insulating layer, and the first corner is more rounded as compared to the second corner. In a particular embodiment, the electronic device can further include an oxide material, wherein a combination of the oxide material and the sidewall spacer substantially fills the opening, and the sidewall spacer includes a nitride material. In another particular embodiment, the electronic device can further include a gate dielectric layer adjacent to the semiconductor layer, and a gate electrode, wherein the gate dielectric layer lies between the semiconductor layer and the gate electrode.

Note that not all of the activities described above in the general description or the examples are required, that a portion of a specific activity may not be required, and that one or more further activities may be performed in addition to those described. Still further, the order in which activities are listed is not necessarily the order in which they are performed.

The illustrations of the embodiments described herein are intended to provide a general understanding of the structure of the various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that a structural substitution, logical substitution, or another change may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. §1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed subject matter requires more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges includes each and every value within that range.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A process of forming an electronic device comprising:
patterning a semiconductor layer to define an opening extending to an insulating layer, wherein the insulating layer lies between a substrate and the semiconductor layer, wherein after patterning a semiconductor layer:
the semiconductor layer has a sidewall and a surface;
the surface is spaced apart from the insulating layer; and
the sidewall extends from the surface towards the insulating layer; and
forming a sidewall spacer adjacent to the sidewall, wherein the sidewall spacer lies within the opening and adjacent to the sidewall, and is spaced apart from the surface.

2. The process of claim 1, wherein forming the sidewall spacer comprises forming the sidewall spacer such that a first elevation, corresponding to a highest point of the sidewall spacer, lies closer to a primary surface of the substrate as compared to a second elevation, corresponding to the surface of the semiconductor layer.

3. The process of claim 1, wherein forming the sidewall spacer comprises forming the sidewall spacer, wherein as seen from a cross-sectional view, the sidewall spacer has a triangular shape.

4. The process of claim 1, wherein forming the sidewall spacer comprises forming the sidewall spacer, wherein as seen from a cross-sectional view, the sidewall spacer has a parabolic shape.

5. The process of claim 1, wherein forming the sidewall spacer comprises forming the sidewall spacer, wherein as seen from a cross-sectional view, the sidewall spacer has a rectangular shape.

6. The process of claim 1, further comprising oxidizing the semiconductor layer, wherein:
the semiconductor layer includes a first corner and a second corner;
the first corner is adjacent to the surface, and the second corner is adjacent to the insulating layer;
the first corner becomes rounded during oxidizing the semiconductor layer; and
the second corner substantially maintains its shape during oxidizing the semiconductor layer.

7. The process of claim 6, further comprising:
depositing an oxide layer that substantially fills the opening; and
polishing the oxide layer to remove a portion of the oxide layer lying outside the opening.

8. The process of claim 7, further comprising:
forming a patterned oxidation-resistant layer over the semiconductor layer before patterning the semiconductor layer; and
removing the patterned oxidation-resistant layer after removing the material.

9. The process of claim 1, wherein forming the sidewall spacer comprises depositing a nitride layer.

10. The process of claim 9, wherein forming the first layer is performed using an inductively coupled plasma.

11. The process of claim 1, further comprising:
forming a gate dielectric layer adjacent to the semiconductor layer; and
forming a gate electrode, wherein the gate dielectric layer lies between the semiconductor layer and the gate electrode.

12. A process of forming an electronic device comprising:
forming a patterned oxidation-resistant layer over a semiconductor layer, wherein an insulating layer lies between a substrate and the semiconductor layer;
patterning the semiconductor layer to define an opening extending to the insulating layer, wherein after patterning the semiconductor layer:
the semiconductor layer has a sidewall and a surface;
the surface is spaced apart from the insulating layer; and
the sidewall extends from the surface towards the insulating layer;
forming a sidewall spacer adjacent to the sidewall, wherein:
the sidewall spacer includes a nitride material;
the sidewall spacer lies within the opening and adjacent to the sidewall, and is spaced apart from the surface; and
a first elevation, corresponding to a highest point of the sidewall spacer, lies closer to a primary surface of the substrate as compared to a second elevation, corresponding to the surface of the semiconductor layer;
oxidizing the semiconductor layer after forming the sidewall spacer, wherein:
the semiconductor layer includes a first corner and a second corner;
the first corner is adjacent to the surface, and the second corner is adjacent to the insulating layer;
the first corner becomes rounded during oxidizing the semiconductor layer; and
the second corner substantially maintains its shape during oxidizing the semiconductor layer;
depositing an oxide layer that substantially fills the opening;
polishing the oxide layer to remove a portion of the oxide layer lying outside the opening;
removing the patterned oxidation-resistant layer after removing the material;
forming a gate dielectric layer adjacent to the semiconductor layer; and
forming a gate electrode, wherein:
the gate dielectric layer lies between the semiconductor layer and the gate electrode; and
the gate dielectric layer and the gate electrode are part of an n-channel transistor.

13. An electronic device comprising:
a substrate;
an insulating layer;
a semiconductor layer, wherein:
the insulating layer lies between the substrate and the semiconductor layer;
the semiconductor layer has a sidewall and a surface;
the surface is spaced apart from the insulating layer; and
the sidewall extends between the insulating layer and the surface; and
a field isolation region overlying the insulating layer and lying adjacent to the sidewall of the semiconductor layer, wherein the field isolation region includes a sidewall spacer that lies adjacent to the sidewall and is spaced apart from the surface.

14. The electronic device of claim 13, wherein a first elevation, corresponding to a highest point of the sidewall spacer, lies closer to a primary surface of the substrate as compared to a second elevation, corresponding to the surface of the semiconductor layer.

15. The electronic device of claim 13, wherein as seen from a cross-sectional view, the sidewall spacer has a triangular shape.

16. The electronic device of claim 13, wherein as seen from a cross-sectional view, the sidewall spacer has a parabolic shape.

17. The electronic device of claim 13, wherein as seen from a cross-sectional view, the sidewall spacer has a rectangular shape.

18. The electronic device of claim 13, wherein:
the semiconductor layer includes a first corner and a second corner;
the first corner is adjacent to the surface, and the second corner is adjacent to the insulating layer; and
the first corner is more rounded as compared to the second corner.

19. The electronic device of claim 18, further comprising an oxide material, wherein:
a combination of the oxide material and the sidewall spacer substantially fills the opening; and
the sidewall spacer comprises a nitride material.

20. The electronic device of claim 18, further comprising:
a gate dielectric layer adjacent to the semiconductor layer; and
a gate electrode, wherein the gate dielectric layer lies between the semiconductor layer and the gate electrode.
